(19) United States
(12) Patent Application Publication
(10) Pub. No.: US 2025/0210549 A1
(43) Pub. Date: Jun. 26, 2025

(54) SEMICONDUCTOR DEVICE AND METHOD FOR MANUFACTURING THE SAME

(71) Applicant: SUMSUNG ELECTRONICS CO., LTD., Suwon-si (KR)

(72) Inventors: Sangjun LEE, Suwon-si (KR); Boram Kim, Suwon-si (KR); Jongseob Kim, Suwon-si (KR); Young Hwan Park, Suwon-si (KR); Jonguk Seo, Suwon-si (KR); Jungseung Yang, Suwon-si (KR); Yongseok Choi, Suwon-si (KR)

(73) Assignee: SAMCUNG ELECTRONICS CO., LTD., Suwon-si (KR)

(21) Appl. No.: 18/808,735

(22) Filed: Aug. 19, 2024

(30) Foreign Application Priority Data
Dec. 22, 2023 (KR) 10-2023-0190301

(51) Int. Cl. H01L 23/64; H01L 29/06; H01L 29/20; H01L 29/66; H01L 29/778

(52) U.S. Cl. CPC H01L 23/647; H10D 30/015; H10D 30/475; H10D 62/124; H10D 62/8503

(57) ABSTRACT

A semiconductor device includes a substrate, a buffer layer on the substrate, the buffer layer including a first high-resistance layer and a second high-resistance layer, a first dislocation blocking layer between the first high-resistance layer and the second high-resistance layer, a channel layer on the buffer layer, the channel layer including a material having a first energy band gap, a barrier layer on the channel layer, the barrier layer including a material having a second energy band gap that is different from the first energy band gap, a gate electrode on the barrier layer, and a gate semiconductor layer between the barrier layer and the gate electrode, where the first dislocation blocking layer includes a plurality of first dislocation blocking patterns arranged at irregular intervals.

### CROSS-REFERENCE TO RELATED APPLICATION

This application is based on and claims priority to Korean Patent Application No. 10-2023-0190301, filed on Dec. 22, 2023, in the Korean Intellectual Property Office, the disclosure of which is incorporated by reference herein in its entirety.

### BACKGROUND

Example embodiments of the disclosure relate to semiconductor devices and methods for manufacturing the same.

The importance of electric power semiconductor devices used in various fields including transportation fields such as electric vehicles, railroads, and electric trams, and renewable energy systems such as solar power generation and wind power generation, and mobile devices is gradually increasing. The electric power semiconductor devices may refer to semiconductor devices that may be used to handle high voltage or high current, and perform functions such as power conversion and control in large power systems or high-output electronic devices. Electric power semiconductor devices may have the ability and durability to handle high power, such that they may handle large amounts of current and withstand high voltage. For example, electric power semiconductor devices may handle voltages from hundreds to thousands of volts and currents from tens to thousands of amperes. Electric power semiconductor devices may improve the efficiency of electrical energy by minimizing power loss. Additionally, electric power semiconductor devices may operate reliably even in environments such as those with high temperatures.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor device with improved electrical characteristics and reliability and a method of manufacturing the same.

Additional aspects will be set forth in part in the description which follows and, in part, will be apparent from the description, or may be learned by practice of the presented embodiments.

According to an aspect of an example embodiment, a semiconductor device may include a substrate, a buffer layer on the substrate, the buffer layer including a first high-resistance layer and a second high-resistance layer, a first dislocation blocking layer between the first high-resistance layer and the second high-resistance layer, a channel layer on the buffer layer, the channel layer including a material having a first energy band gap, a barrier layer on the channel layer, the barrier layer including a material having a second energy band gap that is different from the first energy band gap, a gate electrode on the barrier layer, and a gate semiconductor layer between the barrier layer and the gate electrode, where the first dislocation blocking layer includes a plurality of first dislocation blocking patterns arranged at irregular intervals.

According to an aspect of an example embodiment, a method of manufacturing a semiconductor device may include forming a buffer layer on a substrate, the buffer layer including a high-resistance layer, forming a channel layer on the buffer layer, the channel layer including a material having a first energy band gap, forming a barrier layer on the channel layer, the barrier layer including a material having a second energy band gap that is different from the first energy band gap, forming a gate semiconductor layer on the barrier layer, and forming a gate electrode on the gate semiconductor layer, where the forming of the buffer layer may include forming a first high-resistance layer, forming a first dislocation blocking layer on the first high-resistance layer, the first dislocation blocking layer including a plurality of first dislocation blocking patterns arranged at irregular intervals, and forming a second high-resistance layer on the first dislocation blocking layer.

According to an aspect of an example embodiment, a semiconductor device may include a substrate, a buffer layer on the substrate, the buffer layer including a first high-resistance layer and a second high-resistance layer, the first high-resistance layer and the second high-resistance layer including carbon-doped GaN, a first dislocation blocking layer between the first high-resistance layer and the second high-resistance layer, a channel layer on the buffer layer and including GaN, the channel layer having a first energy band gap, a barrier layer on the channel layer and including AlGaN, the barrier layer having a second energy band gap that is different from the first energy band gap, a gate electrode on the barrier layer, and a gate semiconductor layer between the barrier layer and the gate electrode, where the first dislocation blocking layer includes a plurality of first dislocation blocking patterns arranged at irregular intervals, and a width of each of the plurality of first dislocation blocking patterns is greater than or equal to 100 nm and less than or equal to 200 nm.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 and FIG. 2 are cross-sectional views illustrating a semiconductor device according to one or more embodiments;

FIG. 3 is an enlarged cross-sectional view of area A of FIG. 2 according to one or more embodiments;

FIG. 4 is a diagram illustrating a dislocation blocking pattern according to one or more embodiments;

FIG. 5 is a diagram illustrating a dislocation blocking pattern according to one or more embodiments;

FIG. 6 is a diagram illustrating a dislocation blocking pattern according to one or more embodiments;

FIG. 7 is a diagram illustrating a dislocation blocking pattern according to one or more embodiments;

FIG. 8 is a cross-sectional view illustrating a semiconductor device according to one or more embodiments;

FIG. 9 is a cross-sectional view illustrating a semiconductor device according to one or more embodiments; and

FIG. 10 to FIG. 20 are cross-sectional views illustrating a method of manufacturing a semiconductor device according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

In addition, the size and thickness of each component shown in the drawings are arbitrarily shown for convenience of explanation, so the present disclosure is not necessarily limited to that which is shown. The thickness may be enlarged to clearly express various layers and areas, and the thicknesses of some layers and regions may be exaggerated.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

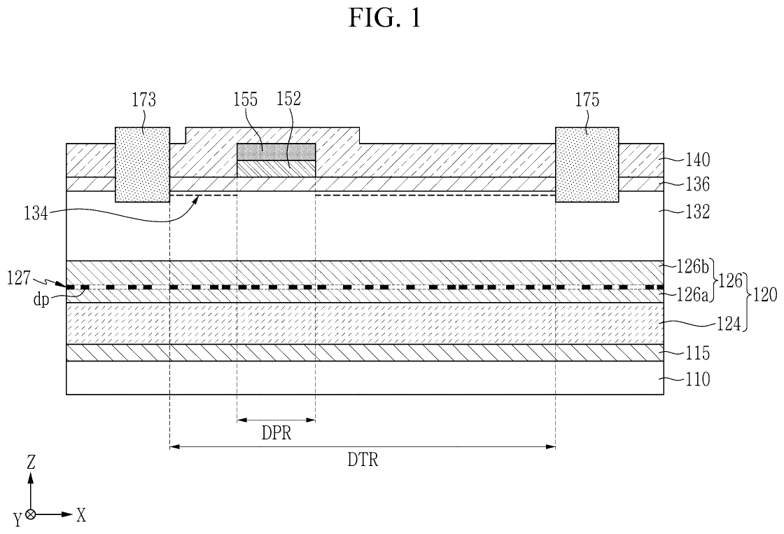

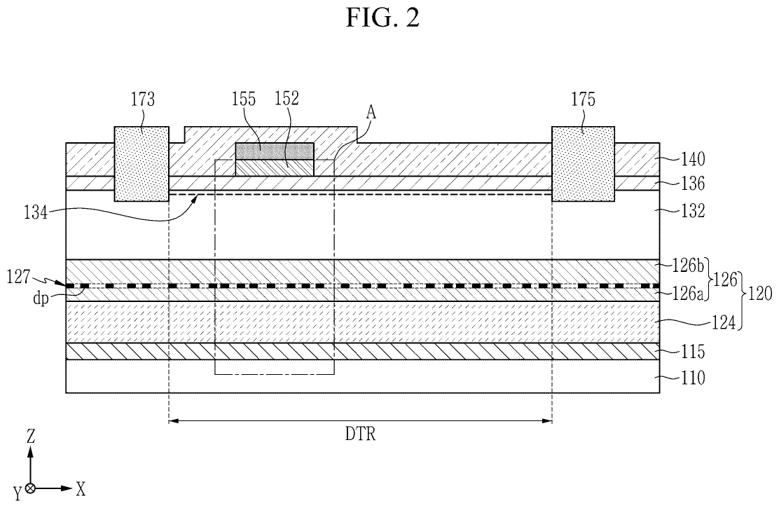

Hereinafter, a semiconductor device according to one or more embodiments will be described with reference to FIGS. 1 and 2 as follows.

FIG. 1 and FIG. 2 are cross-sectional views illustrating a semiconductor device according to one or more embodiments. FIG. 1 shows a case in which a semiconductor device according to one or more embodiments is in an off state, and FIG. 2 shows a case in which a semiconductor device according to one or more embodiments is in an on state.

As shown in FIG. 1, a semiconductor device according to one or more embodiments may include a substrate 110, a buffer layer 120 located on the substrate 110, a channel layer 132 positioned on the buffer layer, a barrier layer 136 positioned above the channel layer 132, the gate electrode 155 positioned above the barrier layer 136, the gate semiconductor layer 152 positioned between the barrier layer 136 and the gate electrode 155, and a dislocation blocking layer 127 located within the buffer layer 120.

The channel layer 132 may be a layer that forms a channel between a source electrode 173 and a drain electrode 175, and a two-dimensional electron gas (2DEG) 134 may be located inside the channel layer 132. The 2DEG 134 may be a charge transport model used in solid physics, and may move freely in two dimensions (for example, in the x-y plane direction) but may be restricted from moving in another dimension (for example, in the z direction) (i.e., the 2DEG 134 may refer to a group of electrons tightly bound within two dimensions). In other words, the 2DEG 134 may exist in a two-dimensional plane within a three-dimensional space. According to one or more embodiments, the 2DEG 134 may appear in a semiconductor heterojunction structure, and may occur at the interface between the channel layer 132 and the barrier layer 136 in a semiconductor device. For example, 2DEG 134 may be generated in the portion closest to the barrier layer 136 within the channel layer 132.

The channel layer 132 may include one or more materials from Group III-V materials, such as nitrides containing at least one of Al, Ga, In, and B. The channel layer 132 may be made of a single layer or multiple layers. The channel layer 132 may be AlₓIn_{y}Ga_{1-x-y}N (0≤x≤1, 0≤y≤1, x+y≤1). For example, the channel layer 132 may include at least one of AlN, GaN, InN, InGaN, AlGaN, AlInN, and AlInGaN. The channel layer 132 may be a layer doped with impurities or a layer not doped with impurities. The thickness of the channel layer 132 may be about several hundred nm or less.

The channel layer 132 may be located on a substrate 110, which will be described later, and the buffer layer 120 may be located between the substrate 110 and the channel layer 132. The substrate 110 and the buffer layer 120 may be layers necessary to form the channel layer 132, and may be omitted in some cases. For example, when a substrate made of GaN is used as the channel layer 132, at least one of the substrate 110 and the buffer layer 120 may be omitted. Considering that the price of a substrate made of GaN is relatively high, the channel layer 132 including GaN may be grown using the substrate 110 made of Si. As the lattice structure of Si and the lattice structure of GaN are different, it may not be easy to grow the channel layer 132 directly on the substrate 110. Accordingly, the buffer layer 120 may first be grown on the substrate 110 and then the channel layer 132 may be grown on the buffer layer 120. Additionally, at least one of the substrate 110 and the buffer layer 120 may be removed from the final structure of the semiconductor device after being used in the manufacturing process.

The substrate 110 may include a semiconductor material. For example, the substrate 110 may include sapphire, Si, SiC, AlN, GaN, or a combination thereof. The substrate 110 may be a silicon on insulator (SOI) substrate. However, the material of the substrate 110 is not limited thereto, and any commonly used substrate may be applied. In some cases, the substrate 110 may include an insulating material. For example, several layers, including the channel layer 132, may be first formed on a semiconductor substrate, then the semiconductor substrate may be removed and replaced with an insulating substrate.

A seed layer 115 may be located on the substrate 110. The seed layer 115 may be located directly above the substrate 110. However, embodiments are not limited thereto, and another predetermined layer may be further positioned between the substrate 110 and the seed layer 115. The seed layer 115 may be a layer that serves as a seed for growing the buffer layer 120, which will be described later, and may be made of a crystal lattice structure that becomes the seed of the buffer layer 120. For example, the seed layer may include AlN.

The buffer layer 120 may be located directly above the seed layer 115. However, embodiments are not limited thereto, and another predetermined layer may be further positioned between the seed layer 115 and the buffer layer 120. The buffer layer 120 is a layer to alleviate the difference in lattice constants and thermal expansion coefficients between the substrate 110 and the channel layer 132. The buffer layer 120 may include one or more materials selected from Group III-V materials, such as nitrides containing at least one of Al, Ga, In, and B. The buffer layer 120 may be AlₓIn_{y}Ga_{1-x-y}N (0≤x≤1, 0≤y≤1, x+y≤1). For example, the buffer layer 120 may include at least one of AlN, GaN, InN, InGaN, AlGaN, AlInN, and AlInGaN. The buffer layer 120 may be made of a single layer or multiple layers.

For example, the buffer layer 120 may include a superlattice layer 124 and a high-resistance layer 126 located on the superlattice layer 124.

The superlattice layer 124 may be located on the seed layer 115.

The superlattice layer 124 may be located directly above the seed layer 115.

However, embodiments are not limited thereto, and another predetermined layer may be further positioned between the seed layer 115 and the superlattice layer 124. The superlattice layer 124 may be located between the seed layer 115 and the channel layer 132. The superlattice layer 124 may be a layer for alleviating the difference in lattice constants and thermal expansion coefficients between the substrate 110 and the channel layer 132. The superlattice layer 124 may include one or more materials selected from Group III-V materials, such as nitrides containing at least one of Al, Ga, In, and B. The superlattice layer 124 may be AlₓIn_{y}Ga_{1-x-y}N (0≤x≤1, 0≤y≤1, x+y≤1). For example, the superlattice layer 124 may include at least one of AlN, GaN, InN, InGaN, AlGaN, AlInN, and AlInGaN. The superlattice layer 124 may be made of a single layer or multiple layers. For example, the superlattice layer 124 may have a structure in which a layer made of AlGaN and a layer made of GaN are repeatedly stacked. For example, AlGaN/GaN/AlGaN/GaN/AlGaN/GaN may be sequentially stacked on the seed layer 115 to form the superlattice layer 124. The number of AlGaN layers and GaN layers constituting the superlattice layer 124 may vary, and the material constituting the superlattice layer 124 may vary.

The high-resistance layer 126 may be located on the superlattice layer 124. The high-resistance layer 126 may be located directly above the superlattice layer 124. However, embodiments are not limited thereto, and another predetermined layer may be further positioned between the superlattice layer 124 and the high-resistance layer 126. The high-resistance layer 126 may be located between the superlattice layer 124 and the channel layer 132. According to one or more embodiments, the high-resistance layer 126 may be used to prevent the semiconductor device, including the channel layer 132, from being externally influenced. The high-resistance layer 126 may be made of a low-conductivity material to electrically insulate the substrate 110 and the channel layer 132. The high-resistance layer 126 may include one or more materials selected from Group III-V materials, such as nitrides containing at least one of Al, Ga, In, and B. The high-resistance layer 126 may be AlₓIn_{y}Ga_{1-x-y}N (0≤x≤1, 0≤y≤1, x y≤1). For example, the high-resistance layer 126 may include at least one of AlN, GaN, InN, InGaN, AlGaN, AlInN, and AlInGaN. The high-resistance layer 126 may be made of a single layer or multiple layers. The high-resistance layer 126 may include impurities in addition to AlₓIn_{y}Ga_{1-x-y}N (0≤x≤1, 0≤y≤1, x+y≤1). For example, the high-resistance layer 126 may include at least one of carbon (C), magnesium (Mg), and iron (Fe) as impurities. The impurity concentration of the high-resistance layer 126 may be different from that of the channel layer 132. For example, the impurity concentration of the high-resistance layer 126 may be greater than that of the channel layer 132. The high-resistance layer 126 may be doped with impurities, and the channel layer 132 may be not doped with impurities. As another example, the impurity concentration of the high-resistance layer 126 may be less than that of the channel layer 132.

In one or more embodiments, a dislocation blocking layer 127, which will be described later, may be located within the high-resistance layer 126. The dislocation blocking layer 127 may be located at a specific level within the high-resistance layer 126. In one or more embodiments, the high-resistance layer 126 may include a first high-resistance layer 126a located below the dislocation blocking layer 127 and a second high-resistance layer 126b located above the dislocation blocking layer 127. That is, the dislocation blocking layer 127 may be located between the first high-resistance layer 126a and the second high-resistance layer 126b. In one or more embodiments, the dislocation blocking layer 127 may be located closer to the lower surface of the channel layer 132 in the vertical direction than the upper surface of the high-resistance layer 126, but is not limited thereto. The second high-resistance layer 126b may also be located between the dislocation blocking patterns dp included in the dislocation blocking layer 127. That is, the second high-resistance layer 126b may cover the upper surfaces of the dislocation blocking patterns dp included in the dislocation blocking layer 127. The lower surface of the first high-resistance layer 126a may contact the upper surface of the superlattice layer 124. The top surface of the first high-resistance layer 126a may contact the dislocation blocking layer 127. The lower surface of the second high-resistance layer 126b may contact the dislocation blocking layer 127. The upper surface of the second high-resistance layer 126b may contact the lower surface of the channel layer 132.

The high-resistance layer 126 may contain defects. For example, the high-resistance layer 126 may include dislocations (e.g., dislocations 128 described later). The dislocation contained within the high-resistance layer 126 may be, for example, a threading dislocation. However, the high-resistance layer 126 may include various other types of defects therein. The dislocations may extend, for example, from the bottom surface of the high-resistance layer 126 to the interior of the high-resistance layer 126. In one or more embodiments, the second high-resistance layer 126b may have a lower defect density than the first high-resistance layer 126a. For example, the second high-resistance layer 126b may have a smaller number of threading dislocations per unit volume than the first high-resistance layer 126a. That is, due to the dislocation patterns dp in the dislocation blocking layer 127, the threading dislocations extending from the bottom surface of the high-resistance layer 126 may be blocked or prevented from extending through the second high-resistance layer 126b, resulting in a lower defect density than a defect density of the first high-resistance layer 126a.

In FIG. 1 and FIG. 2, the buffer layer 120 is shown as including only the superlattice layer 124 and the high-resistance layer 126, but the buffer layer 120 may further include predetermined layers other than the superlattice layer 124 and the high-resistance layer 126. For example, the buffer layer 120 may further include predetermined other layers positioned between the seed layer 115 and the superlattice layer 124, between the superlattice layer 124 and the high-resistance layer 126, and/or between the high-resistance layer 126 and the channel layer 132.

The barrier layer 136 may be located on the channel layer 132. The barrier layer 136 may be located directly above the channel layer 132. However, embodiments are not limited thereto, and another predetermined layer may be further positioned between the channel layer 132 and the barrier layer 136. An area of the barrier layer 136 that overlaps the channel layer 132 may be a drift region DTR. The drift region DTR may be located between the source electrode 173 and the drain electrode 175. When a dislocation difference occurs between the source electrode 173 and the drain electrode 175, carriers may move in the drift region DTR. Depending on whether voltage is applied to a gate electrode 155 and the magnitude of the voltage applied to the gate electrode 155, the semiconductor device according to one or more embodiments may be turned on/off, and accordingly, the carriers moving in the drift region DTR may be enabled or blocked.

The barrier layer 136 may include one or more materials selected from Group III-V materials, such as nitrides containing at least one of Al, Ga, In, and B. The barrier layer 136 may be AlₓIn_{y}Ga_{1-x-y}N (0≤x≤1, 0≤y≤1, x+y≤1). The barrier layer 136 may include at least one of GaN, InN, AlGaN, AlInN, InGaN, AlN, AlInGaN, etc. The energy band gap of the barrier layer 136 may be adjusted by the composition ratio of Al and/or In. The barrier layer 136 may be doped with a predetermined impurity. The impurity doped into the barrier layer 136 may be a p-type dopant that may provide holes. For example, the impurity doped into the barrier layer 136 may be magnesium (Mg). By increasing or decreasing the impurity doping concentration of the barrier layer 136, the threshold voltage, on-resistance, etc., of the semiconductor device according to one or more embodiments may be adjusted.

The barrier layer 136 may include a semiconductor material having different characteristics from the channel layer 132. The barrier layer 136 may be different from the channel layer 132 in at least one of polarization characteristics, energy band gap, or lattice constant. For example, the barrier layer 136 may include a material having a different energy band gap than the channel layer 132. The barrier layer 136 may have a higher energy band gap than the channel layer 132 and may have a higher electrical polarization rate than the channel layer 132. The 2DEG 134 may be induced in the channel layer 132 having a relatively low electrical polarization rate by the barrier layer 136. In this regard, the barrier layer 136 may also be referred to as a channel supply layer or a 2DEG supply layer. The 2DEG 134 may be formed within the portion of the channel layer 132 located below the interface between the channel layer 132 and the barrier layer 136. The 2DEG 134 may have very high electron mobility.

The barrier layer 136 may be made of a single layer or multiple layers. When the barrier layer 136 is made of multiple layers, the materials of each layer constituting the multiple layers may have different energy band gaps. The various layers constituting the barrier layer 136 may be arranged so that the energy band gap increases as the layers approach the channel layer 132.

The gate electrode 155 may be located on the barrier layer 136. The gate electrode 155 may overlap a portion of the barrier layer 136. The gate electrode 155 may overlap a portion of the drift region DTR of the channel layer 132. The gate electrode 155 may be located between the source electrode 173 and the drain electrode 175. The gate electrode 155 may be spaced apart from the source electrode 173 and the drain electrode 175.

The gate electrode 155 may include a conductive material. For example, the gate electrode 155 may include a metal, a metal alloy, a conductive metal nitride, a metal silicide, a doped semiconductor material, a conductive metal oxide, or a conductive metal nitride. For example, the gate electrode 155 may be made of titanium nitride (TiN), tantalum carbide (TaC), tantalum nitride (TaN), titanium silicon nitride (TiSiN), tantalum silicon nitride (TaSiN), tantalum titanium nitride (TaTiN), or titanium, aluminum nitride (TiAIN), tantalum aluminum nitride (TaAIN), tungsten nitride (WN), ruthenium (Ru), titanium aluminum (TiAI), titanium aluminum carbonitride (TiAIC-N), titanium aluminum carbide (TiAIC), titanium carbide (TiC), tantalum carbonitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or any combination thereof, but embodiments are not limited thereto. The gate electrode 155 may be made of a single layer or multiple layers.

The gate semiconductor layer 152 may be located between the barrier layer 136 and the gate electrode 155. That is, the gate semiconductor layer 152 may be located on the barrier layer 136, and the gate electrode 155 may be located on the gate semiconductor layer 152. The gate electrode 155 may be in ohmic contact or Schottky contact with the gate semiconductor layer 152. The gate electrode 155 may overlap the gate semiconductor layer 152. The gate electrode 155 may completely overlap the gate semiconductor layer 152 in a vertical direction, and the upper surface of the gate semiconductor layer 152 may be entirely covered by the gate electrode 155. That is, the gate semiconductor layer 152 may have substantially the same planar shape as the gate electrode 155.

The gate semiconductor layer 152 may be located between the source electrode 173 and the drain electrode 175. The gate semiconductor layer 152 may be spaced apart from the source electrode 173 and the drain electrode 175. The gate semiconductor layer 152 may be located closer to the source electrode 173 than the drain electrode 175. That is, the separation distance between the gate semiconductor layer 152 and the source electrode 173 may be smaller than the separation distance between the gate semiconductor layer 152 and the drain electrode 175.

The gate semiconductor layer 152 may include one or more materials selected from Group III-V materials, such as nitrides containing at least one of Al, Ga, In, and B. The gate semiconductor layer 152 may be AlₓInyGa_{1-x-y}N (0≤x≤1, 0≤y≤1, x+y≤1). For example, the gate semiconductor layer 152 may include at least one of AlN, GaN, InN, InGaN, AlGaN, AlInN, and AlInGaN. The gate semiconductor layer 152 may include a material having an energy band gap different from that of the barrier layer 136. For example, the gate semiconductor layer 152 may include GaN, and the barrier layer 136 may include AlGaN. The gate semiconductor layer 152 may be doped with a predetermined impurity. The impurity doped into the gate semiconductor layer 152 may be a p-type dopant that may provide holes. For example, the gate semiconductor layer 152 may include GaN doped with p-type impurities. That is, the gate semiconductor layer 152 may be made of a p-GaN layer. However, embodiments are not limited thereto, and the gate semiconductor layer 152 may be a p-AlGaN layer. The impurity doped into the gate semiconductor layer 152 may be magnesium (Mg). The gate semiconductor layer 152 may be made of a single layer or multiple layers.

The depletion region DPR may be formed in the channel layer 132 by the gate semiconductor layer 152. The depletion region DPR may be located within the drift region DTR, and may have a narrower width than the drift region DTR. As the gate semiconductor layer 152 having an energy band gap different from that of the barrier layer 136 is positioned on the barrier layer 136, the energy band of the portion of the barrier layer 136 that is overlapped by the gate semiconductor layer 152 may increase. Accordingly, a depletion region DPR may be formed in the area of the channel layer 132 that is overlapped by the gate semiconductor layer 152. The depletion region DPR may be a region in the channel path of the channel layer 132 where the 2DEG 134 is not formed or may have a lower electron concentration than the remaining regions. That is, the depletion region DPR may refer to a region where the flow of the 2DEG 134 is interrupted within the drift region DTR. As the depletion region DPR occurs, current does not flow between the source electrode 173 and the drain electrode 175, and the channel path may be blocked. Accordingly, the semiconductor device according to one or more embodiments may have normally off characteristics.

That is, the semiconductor device according to one or more embodiments may be a normally off high-electron mobility transistor (HEMT). As shown in FIG. 1, in a normal state in which no voltage is applied to the gate electrode 155, a depletion region DPR exists, and the semiconductor device according to one or more embodiments may be in an off state. As shown in FIG. 2, when a voltage greater than the threshold voltage is applied to the gate electrode 155, the depletion region DPR disappears and the 2DEG 134 within the drift region DTR may be unbroken and connected. That is, the 2DEG 134 may be formed throughout the channel path between the source electrode 173 and the drain electrode 175, and the semiconductor device according to one or more embodiments may be in an on state.

A semiconductor device according to one or more embodiments may include semiconductor layers with different electrical polarization characteristics, and a semiconductor layer with a relatively large polarization rate may induce a 2DEG 134 in another semiconductor layer in heterojunction with it. This 2DEG 134 may be used as a channel between the source electrode 173 and the drain electrode 175, and the flow of this 2DEG 134 may be controlled by a bias voltage applied to the gate electrode 155. In the gate-off state, the flow of the 2DEG 134 is blocked, so current may not flow between the source electrode 173 and the drain electrode 175. As the 2DEG 134 continues to flow in the gate-on state, current may flow between the source electrode 173 and the drain electrode 175.

Although the case where the semiconductor device according to one or more embodiments is a normally-off HEMT has been described above, embodiments are not limited thereto. For example, the semiconductor device according to one or more embodiments may be a normally-on HEMT. In the case of a normally-on HEMT, the gate semiconductor layer 152 may be omitted, and thus the gate electrode 155 may be located directly above the barrier layer 136. That is, the gate electrode 155 may contact the barrier layer 136. In this structure, the 2DEG 134 may be used as a channel while no voltage is applied to the gate electrode 155, and current flow may occur between the source electrode 173 and the drain electrode 175. Additionally, when negative voltage is applied to the gate electrode 155, a depletion region DPR may occur at the bottom of the gate electrode 155 in which the flow of the 2DEG 134 is cut off.

The dislocation blocking layer 127 may be located within the high-resistance layer 126. In one or more embodiments, the dislocation blocking layer 127 may be located at a specific level within the high-resistance layer 126. Referring to FIGS. 1 and 2, the dislocation blocking layer 127 may be positioned at a predetermined distance from the lower surface of the high-resistance layer 126 in the vertical direction. For example, the total thickness of the high-resistance layer 126 may be about 1 μm. For example, the dislocation blocking layer 127 may be positioned at a distance of about 50 nm from the lower surface of the first high-resistance layer 126a in the vertical direction. However, the location of the dislocation blocking layer 127 within the high-resistance layer 126 is not limited thereto. The dislocation blocking layer 127 may include a plurality of dislocation blocking patterns dp arranged inside to be spaced apart from each other.

A plurality of dislocation blocking patterns dp included in the dislocation blocking layer 127 may be located at a specific level within the high-resistance layer 126. The lower surfaces of the dislocation blocking patterns dp may be located on a plane at the same level. That is, the dislocation blocking patterns dp may have lower surfaces located at the same distance in the vertical direction from the bottom surface of the high-resistance layer 126. The upper and lower surfaces of the dislocation blocking patterns dp may contact the high-resistance layer 126. The upper surfaces of the dislocation blocking patterns dp may contact the second high-resistance layer 126b. The upper surface of each of the dislocation blocking patterns dp may be covered by the second high-resistance layer 126b. The lower surfaces of the dislocation blocking patterns dp may contact the first high-resistance layer 126a.

A plurality of dislocation blocking patterns dp may be arranged at irregular intervals. For example, a plurality of dislocation blocking patterns dp may be positioned to be spaced apart from each other at varied horizontal (i.e., x-direction) distances. That is, referring to FIGS. 1 and 2, a plurality of dislocation blocking patterns dp may be positioned to be spaced apart in the first direction (X) or the second direction (Y). The distance in the horizontal direction (first direction (X) or second direction (Y)) between the plurality of dislocation blocking patterns dp included in the dislocation blocking layer 127 may not be constant. That is, the plurality of dislocation blocking patterns dp included in the dislocation blocking layer 127 may be arranged at irregular intervals, such that the dislocation blocking patterns are spaced apart at varied distances on the same level plane in the high-resistance layer 126.

Each of the plurality of dislocation blocking patterns dp included in the dislocation blocking layer 127 may have a curved upper surface. Each of the plurality of dislocation blocking patterns dp included in the dislocation blocking layer 127 may have an upper surface that protrudes convexly in the vertical direction. Each dislocation blocking pattern dp may have a flat bottom surface. The thickness of each of the dislocation blocking patterns dp may gradually become thicker from both ends to the center of each of the dislocation blocking patterns dp. That is, each of the dislocation blocking patterns may have a smaller thickness at horizontal edges and a larger thickness towards the center, in a parabola shape. The width of each of the plurality of dislocation blocking patterns dp in the horizontal direction (first direction (X) or second direction (Y)) may be several hundred nanometers (nm), and in one or more example embodiments, about 100 nm or more and about 200 nm or less. In one or more embodiments, all of the dislocation blocking patterns dp included in the dislocation blocking layer 127 may have substantially the same width, or at least some of the dislocation blocking patterns dp may have different widths. In one or more embodiments, all or some of the dislocation blocking patterns dp may have different widths in the first direction (X direction) and in the second direction (Y direction). When viewed on a plane parallel to the first direction (X direction) and the second direction (Y direction), all or some of the dislocation blocking patterns dp may have a square, circular, oval, or irregular shape. In one or more embodiments, the width of each of the dislocation blocking patterns dp in at least one of the first direction (X direction) and the second direction (Y direction) may be about 100 nm to about 200 nm. The width may refer to a maximum width in the corresponding direction.

In one or more embodiments, all or some of the dislocation blocking patterns dp may have the same thickness or different thicknesses. In one or more embodiments, the thickness of each of the dislocation blocking patterns dp may be less than or equal to about 20 nm. As an example, the thickness of each of the dislocation blocking patterns dp may be about 0.5 nm or more and about 20 nm or less. The thickness may refer to a maximum thickness in the third direction (Z direction), as the thicknesses of the dislocation blocking patterns dp may vary along the horizontal directions. The thickness of the center of the dislocation blocking pattern dp may be largest. Accordingly, the thickness of the center of the dislocation blocking pattern dp may be less than or equal to about 20 nm.

The dislocation blocking patterns dp may include an insulating material. The insulating material may be selected as a material that is easy to form in the high-resistance layer 126 during the process of forming the high-resistance layer 126. For example, at least one element among the elements constituting the material included in the high-resistance layer 126 may also be included as an element constituting the insulating material included in the dislocation blocking patterns dp. For example, when the high-resistance layer 126 includes nitride, the dislocation blocking patterns dp may also include nitride. In one or more embodiments, when the high-resistance layer 126 includes GaN, the dislocation blocking patterns dp may be a nitride containing a material other than gallium (Ga) as an element. For example, the dislocation blocking patterns dp may include indium nitride (InNx). In one or more embodiments, the dislocation blocking patterns dp may be formed in-situ during the process of forming the high-resistance layer 126, in the same process as the process of forming the high-resistance layer 126. That is, the dislocation blocking patterns dp may be formed by controlling the types and amounts of materials injected into the chamber during the process of forming the high-resistance layer 126. At least one of the materials forming the high-resistance layer 126 may also be used in the process of forming the dislocation blocking patterns dp. For example, when the high-resistance layer 126 includes GaN and the dislocation blocking patterns dp includes indium nitride (InNx), ammonia (NH3) may be used as a source material in the process of forming the channel layer 132 and the process of forming the dislocation blocking patterns dp. For example, ammonia (NH3) gas may be used as a source gas in the process of forming the high-resistance layer 126 and the process of forming the dislocation blocking patterns dp.

The lower surfaces of the dislocation blocking patterns dp may contact the first high-resistance layer 126a. The upper surface of the dislocation blocking patterns dp may be covered by the second high-resistance layer 126b. The second high-resistance layer 126b may contact the top surface of at least some of the dislocation blocking patterns dp. The second high-resistance layer 126b may fill the remaining area of the dislocation blocking layer 127 except for the portion where the dislocation blocking patterns dp are located. That is, the second high-resistance layer 126b may be located between the dislocation blocking patterns dp. The second high-resistance layer 126b may surround side surfaces (e.g., horizontal edges) of the dislocation blocking patterns dp.

The buffer layer 120, the dislocation blocking layer 127, the channel layer 132, the barrier layer 136, and the gate semiconductor layer 152 described above may be sequentially stacked on the substrate 110. In the semiconductor device according to one or more embodiments, at least one of the buffer layer 120, the channel layer 132, the barrier layer 136, or the gate semiconductor layer 152 may be omitted. The buffer layer 120, the channel layer 132, the barrier layer 136, and the gate semiconductor layer 152 may be made of the same semiconductor material, taking into account the role of each layer and the performance required for the semiconductor device. Therefore, the material composition ratio of each layer may be different.

The source electrode 173 and the drain electrode 175 may be located on the channel layer 132. The source electrode 173 and the drain electrode 175 may be spaced apart from each other, and the gate electrode 155 and the gate semiconductor layer 152 may be positioned between the source electrode 173 and the drain electrode 175. The gate electrode 155 and the gate semiconductor layer 152 are spaced apart from the source electrode 173 and the drain electrode 175. The source electrode 173 may be electrically connected to the channel layer 132 on one side of the gate electrode 155. The drain electrode 175 may be electrically connected to the channel layer 132 on the other side of the gate electrode 155. The source electrode 173 and the drain electrode 175 may be located outside the drift region DTR of the channel layer 132. The boundary between the source electrode 173 and the channel layer 132 may be one edge of the drift region DTR. Likewise, the boundary between the drain electrode 175 and the channel layer 132 may be the other edge of the drift region DTR.

The source electrode 173 and the drain electrode 175 may include a conductive material. For example, the source electrode 173 and the drain electrode 175 may include metal, metal alloy, conductive metal nitride, metal silicide, a doped semiconductor material, conductive metal oxide, or conductive metal nitride. For example, the source electrode 173 and the drain electrode 175 may be made of titanium nitride (TiN), tantalum carbide (TaC), tantalum nitride (TaN), titanium silicon nitride (TiSiN), tantalum silicon nitride (TaSiN), or tantalum titanium, nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or combinations thereof, but they are not limited thereto. The source electrode 173 and the drain electrode 175 may be made of a single layer or multiple layers. The source electrode 173 and the drain electrode 175 may be in ohmic contact with the channel layer 132. The region contacting the source electrode 173 and the drain electrode 175 within the channel layer 132 may be doped at a relatively high concentration compared to other regions.

A semiconductor device according to one or more embodiments may include a barrier layer 136 and a protective layer 140 covering the top surface of the gate electrode 155. The protective layer 140 may cover the side surfaces of the gate semiconductor layer 152 and the gate electrode 155. The protective layer 140 may cover a portion of the side surface of the source electrode 173 and a portion of the side surface of the drain electrode 175. The lower surface of the protective layer 140 may contact the barrier layer 136, the gate electrode 155, and the gate semiconductor layer 152.

The protective layer 140 may include an insulating material. For example, the protective layer 140 may include materials such as SiO₂, SiN, SiON, Al₂O₃, etc. The protective layer 140 may be made of a single layer or multiple layers. Although not shown, the protective layer 140 may include a lower protective layer and an upper protective layer that are sequentially stacked. In some cases, the protective layer 140 may include three or more layers.

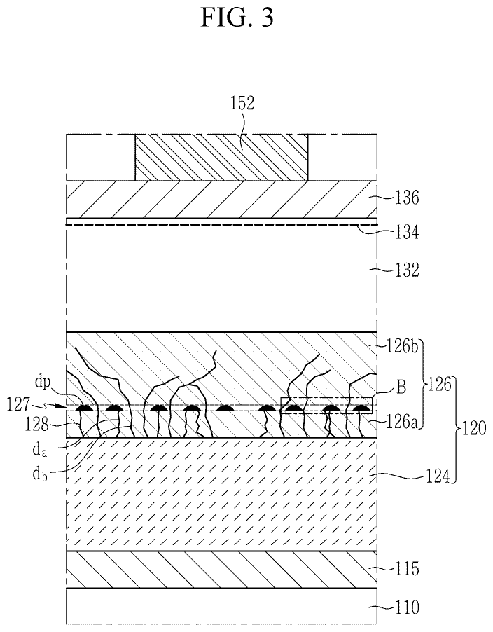

FIG. 3 is an enlarged cross-sectional view of area A of FIG. 2 according to one or more embodiments.

Referring to FIG. 3, the semiconductor device according to one or more embodiments may include a dislocation blocking layer 127 formed within the high-resistance layer 126. The dislocation blocking layer 127 may be located at a specific level within the high-resistance layer 126. The dislocation blocking layer 127 may include a plurality of dislocation blocking patterns dp arranged at irregular intervals and spaced apart from each other. In one or more embodiments, the dislocation blocking patterns dp may be arranged at irregular intervals such that the dislocation blocking patterns dp are spaced apart at varied distances on a plane at the same level within the high-resistance layer 126.

The thickness of the high-resistance layer 126 may be appropriately selected in consideration of the dislocation density in the area adjacent to the top surface of the high-resistance layer 126, the flatness of the top surface of the high-resistance layer 126, the process time, etc. When dislocation blocking patterns dp are included inside the high-resistance layer 126, in order to have a sufficiently flat surface of the high-resistance layer 126, the second high-resistance layer 126b may be be formed with at least a predetermined thickness. However, if the thickness of the second high-resistance layer 126b is too thick, the process time may excessively increase. In one or more embodiments, the second high-resistance layer 126b may have a thickness of about 100 nm to about 1 μm.

The high-resistance layer 126 may include a plurality of dislocations 128 formed therein. For example, the plurality of dislocations 128 formed inside the high-resistance layer 126 may be threading dislocations. However, the type of defects located inside the high-resistance layer 126 is not limited, and various types of defects may be located therein. Referring to FIG. 3, dislocations 128 may be formed from the bottom surface of the high-resistance layer 126 and extend into the interior of the high-resistance layer 126. Specifically, the dislocations 128 may propagate from the bottom surface of the first high-resistance layer 126a to the inside of the first high-resistance layer 126a. Some of the dislocations 128 propagating into the first high-resistance layer 126a may penetrate the dislocation blocking layer 127 and further propagate into the second high-resistance layer 126b of the channel layer 132. Some of the dislocations 128 extending inside the first high-resistance layer 126a of the channel layer 132 may have one end contacting the bottom surface of the dislocation blocking patterns dp included in the dislocation blocking layer 127.

Among the dislocations 128 included in the first high-resistance layer 126a, the dislocations 128 whose ends contact the dislocation blocking patterns dp may not propagate into the second high-resistance layer 126b. For example, in the case of a voltage applied to a dislocation da, the dislocation may propagate from the bottom surface of the first high-resistance layer 126a to the inside of the first high-resistance layer 126a, and may meet the bottom surface of the dislocation blocking patterns dp. In this case, dislocations 128 such as a dislocation da may no longer propagate to other areas within the high-resistance layer 126. That is, the dislocation blocking patterns dp may prevent the dislocations 128 from extending to an upper surface of the high-resistance layer 126. Accordingly, the second high-resistance layer 126b may have a lower dislocation density compared to the first high-resistance layer 126a.

In the case of dislocations 128 included in the first high-resistance layer 126a that do not contact the dislocation blocking patterns dp, the direction in which the dislocations 128 propagate may change. When a plurality of dislocation blocking patterns dp are located inside the high-resistance layer 126, the high-resistance layer 126 may not be grown on the upper surface of the dislocation blocking patterns dp. Accordingly, the high-resistance layer 126 may not grow upward from the bottom surface of the high-resistance layer 126, but may grow in a lateral direction of the high-resistance layer 126. In this case, the direction in which the dislocations 128 contained within the high-resistance layer 126 propagate may also change to the side direction of the high-resistance layer 126. For example, in the case of the dislocation d_{b} depicted in FIG. 3, the dislocation d_{b} may propagate from the bottom surface of the high-resistance layer 126 towards the top surface of the high-resistance layer 126, and at a position adjacent to the dislocation blocking patterns dp, the propagation direction may change to the side direction of the high-resistance layer 126. Due to the dislocation blocking patterns dp, the number of dislocations 128 that do not propagate to the upper surface of the high-resistance layer 126 may increase (i.e., the number of dislocations 128 that propagate toward the upper surface of the high-resistance layer 126 is reduced), and accordingly, the dislocation density at the interface between the high-resistance layer 126 and the barrier layer 136 may decrease.

In a semiconductor device having the same or similar structure as described with reference to FIGS. 1 to 3, a 2DEG 134 may be located at the interface between the channel layer 132 and the barrier layer 136. The 2DEG 134 may provide a path through which electrons flow when the semiconductor device is turned on. Therefore, in order to improve the electrical characteristics of the semiconductor device, it may be important to minimize the density of defects located inside the channel layer 132. That is, the density of defects in the high-resistance layer 126 located immediately below the channel layer 132 may affect the defect density of the channel layer 132. For example, when the defect density located in the area adjacent to the upper surface of the high-resistance layer 126 inside the high-resistance layer 126 is high, the channel layer 132 may be continuously grown directly on the high-resistance layer 126, and the defect density may increase. For example, as the channel layer 132 is grown directly on the high-resistance layer 126, defects located at the interface between the high-resistance layer 126 and the channel layer 132 are transferred into the channel layer 132.

In the case of the semiconductor device according to one or more embodiments, as the dislocation density within the high-resistance layer 126 decreases, the defect density at the interface between the high-resistance layer 126 and the channel layer 132 and inside the channel layer 132 decreases, and thus the electrical characteristics of the semiconductor device may be improved.

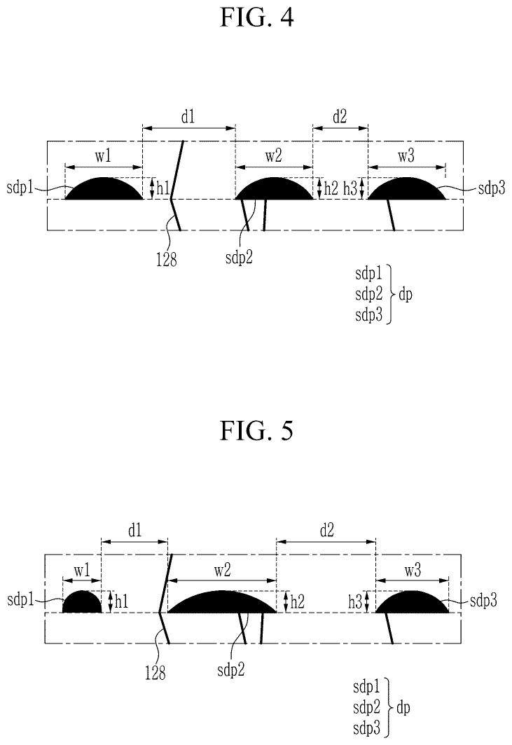

FIG. 4 to FIG. 7 are diagrams illustrating dislocation blocking patterns according to one or more embodiments. Specifically, FIGS. 4 to 7 are enlarged cross-sectional views of various examples corresponding to area B in FIG. 3. FIG. 4 to FIG. 7 show a first sub-pattern sdp1, a second sub-pattern sdp2, and a third sub-pattern sdp3 that are dislocation blocking patterns dp.

As described with reference to FIGS. 1 to 3, the dislocation blocking patterns dp may be arranged at irregular intervals. The spacing between the plurality of dislocation blocking patterns dp included in the dislocation blocking layer 127 may be different. For example, referring to FIGS. 4 to 7, a distance d1 between the first sub-pattern sdp1 and the second sub-pattern sdp2, and the distance d2 between the second sub-pattern sdp2 and the third sub-pattern sdp3 may be different. However, embodiments are not limited thereto, and the distance d1 between the first sub-pattern sdp1 and the second sub-pattern sdp2, and the distance d2 between the second sub-pattern sdp2 and the third sub-pattern sdp3 may be substantially the same.

In one or more embodiments, the sizes of the dislocation blocking patterns dp may be substantially the same. That is, referring to FIG. 4, the dislocation blocking patterns dp may have substantially the same width and thickness. Specifically, as shown in FIG. 4, the width w1 of the first sub-pattern sdp1, the width w2 of the second sub-pattern sdp2, and the width w3 of the third sub-pattern sdp3 are may be the same. Additionally, as shown in FIG. 4, the thickness h1 of the first sub-pattern sdp1, the thickness h2 of the second sub-pattern sdp2, and the thickness h3 of the third sub-pattern sdp3 are substantially may be the same.

In one or more embodiments, the widths of the dislocation blocking patterns dp may be different from each other, and the thicknesses may be substantially the same. Specifically, as shown in FIG. 5, the width w1 of the first sub-pattern sdp1, the width w2 of the second sub-pattern sdp2, and the width w3 of the third sub-pattern sdp3 each may be different. Also, as shown in FIG. 5, the thickness h1 of the first sub-pattern sdp1, the thickness h2 of the second sub-pattern sdp2, and the thickness h3 of the third sub-pattern sdp3 are substantially the same.

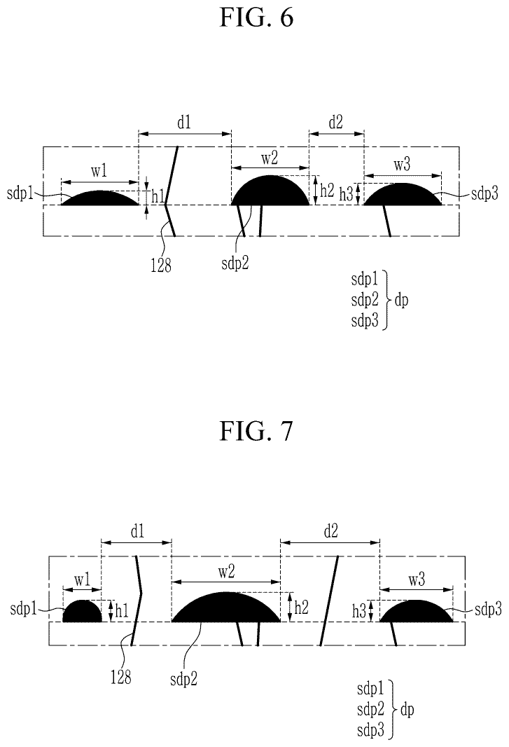

In one or more embodiments, the width of the dislocation blocking patterns dp may be substantially the same, and the thickness may be different. Specifically, as shown in FIG. 6, the width w1 of the first sub-pattern sdp1, the width w2 of the second sub-pattern sdp2, and the width w3 of the third sub-pattern sdp3 may be substantially the same. Also, as shown in FIG. 6, the thickness h1 of the first sub-pattern sdp1, the thickness h2 of the second sub-pattern sdp2, and the thickness h3 of the third sub-pattern sdp3 may each be different from each other.

In one or more embodiments, the dislocation blocking patterns dp may have different widths and different thicknesses. Specifically, as shown in FIG. 7, the width w1 of the first sub-pattern sdp1, the width w2 of the second sub-pattern sdp2, and the width w3 of the third sub-pattern sdp3 each may be different. As depicted in FIG. 7, the thickness h1 of the first sub-pattern sdp1, the thickness h2 of the second sub-pattern sdp2, and the thickness h3 of the third sub-pattern sdp3 may each be different from one another.

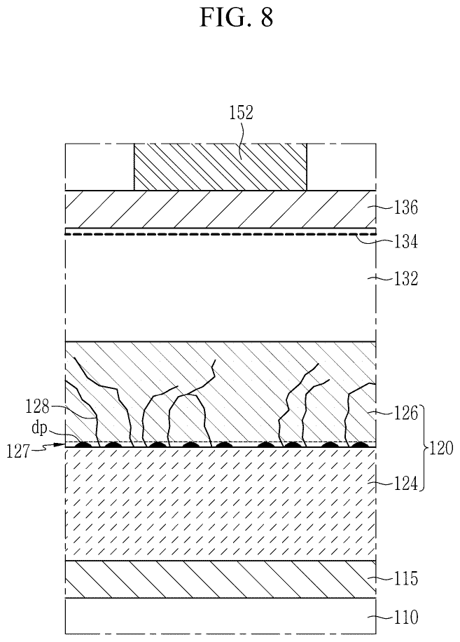

FIG. 8 is a cross-sectional view illustrating a semiconductor device according to one or more embodiments. FIG. 8 may include features that are the same or similar as those described above, and repeated descriptions may be omitted. In FIG. 8, the location of the dislocation blocking layer 127 within the high-resistance layer 126 may be slightly different from those described above.

Referring to FIG. 8, in one or more embodiments, the dislocation blocking layer 127 may be located between the high-resistance layer 126 and a superlattice layer 124. The upper surface of the dislocation blocking layer 127 may contact the high-resistance layer 126, and the lower surface of the dislocation blocking layer 127 may contact the upper surface of the superlattice layer 124. That is, the dislocation blocking layer 127 may be located directly above the superlattice layer 124.

The thickness of the high-resistance layer 126 may be appropriately selected in consideration of the dislocation density in the area adjacent to the top surface of the high-resistance layer 126, the flatness of the top surface of the high-resistance layer 126, the process time, etc. In particular, in order to improve the flatness of the upper surface of the high-resistance layer 126, it may be advantageous to form the dislocation blocking patterns dp at the beginning of the process of forming the high-resistance layer 126. As shown in FIG. 8, when the dislocation blocking layer 127 including the dislocation blocking patterns dp is located directly above the superlattice layer 124, compared to the semiconductor device described with reference to FIGS. 1 to 3, the flatness of the upper surface of the channel layer 132 may be improved.

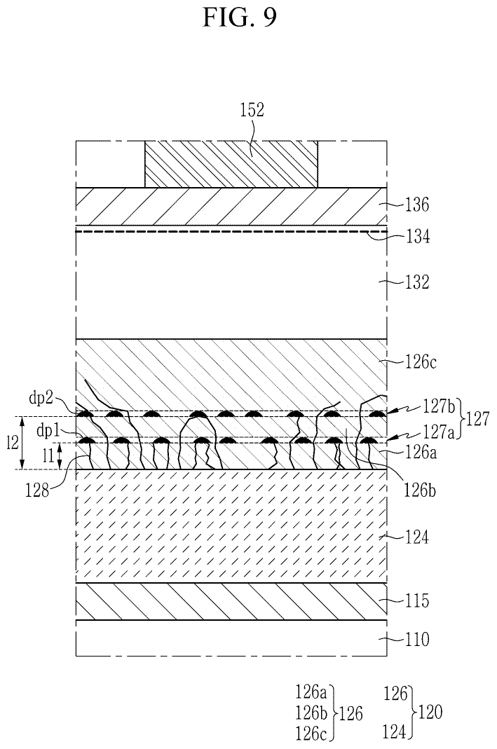

FIG. 9 is a cross-sectional view illustrating a semiconductor device according to one or more embodiments. FIG. 9 may include features that are the same or similar as those described above, and repeated descriptions may be omitted. In the embodiment shown in FIG. 9, the number of dislocation blocking layers 127 included in the high-resistance layer 126 may be slightly different from the previous embodiment.

Referring to FIG. 9, a semiconductor device according to one or more embodiments may include two dislocation blocking layers 127 located at different levels within the high-resistance layer 126. However, the number of dislocation blocking layers 127 located in the high-resistance layer 126 is not limited thereto. For example, the high-resistance layer 126 may include three or more dislocation blocking layers 127. In one or more embodiments, when the high-resistance layer 126 includes two or more dislocation blocking layers 127, the dislocation blocking layer 127 located on the uppermost layer has a higher resistance layer, and the dislocation blocking layer 127 may be located closer to the lower surface of 126 in the vertical direction.

Referring to FIG. 9, the high-resistance layer 126 may include a first dislocation blocking layer 127a located at the first level 11 with respect to the bottom surface of the high-resistance layer 126, and a second dislocation blocking layer 127b located at the second level 12. Among the two dislocation blocking layers 127a and 127b, the second dislocation blocking layer 127b located on the topmost layer may be positioned closer to the bottom surface of the high-resistance layer 126 in the vertical direction than to the top surface of the high-resistance layer 126. In one or more embodiments, the second level 12 may be located higher than the first level 11 within the high-resistance layer 126. The first dislocation blocking layer 127a may include a plurality of first dislocation blocking patterns dp1 arranged at irregular intervals such that the first dislocation blocking patterns dp1 are spaced apart at varied distances along the horizontal direction at a thickness of the first level 11. The second dislocation blocking layer 127b may include a plurality of second dislocation blocking patterns dp2 arranged at irregular intervals such that the second dislocation blocking patterns dp2 are spaced apart at varied distances along the horizontal direction at a thickness of the second level 12.

In one or more embodiments, the first dislocation blocking patterns dp1 and the second dislocation blocking patterns dp2 may or may not overlap each other in the vertical direction. For example, some of the second dislocation blocking patterns dp2 may overlap some of the first dislocation blocking patterns dp1 in the vertical direction, and some of the second dislocation blocking patterns dp2 may not overlap some of the first dislocation blocking patterns dp1 in the vertical direction.

The high-resistance layer 126 may include first to third high-resistance layers 126a to 126c. The first high-resistance layer 126a may be located between the top surface of the superlattice layer 124 and the first dislocation blocking layer 127a. The second high-resistance layer 126b may be located between the first dislocation blocking layer 127a and the second dislocation blocking layer 127b. The second high-resistance layer 126b may also be located between the first dislocation blocking patterns dp1 included in the first dislocation blocking layer 127a. That is, the second high-resistance layer 126b may cover the upper surfaces of the first dislocation blocking patterns dp1 included in the first dislocation blocking layer 127a.

The third high-resistance layer 126c may be located between the second dislocation blocking layer 127b and the channel layer 132. The third high-resistance layer 126c may also be located between the second dislocation blocking patterns dp2 included in the second dislocation blocking layer 127b. That is, the third high-resistance layer 126c may cover the upper surfaces of the second dislocation blocking patterns dp2 included in the second dislocation blocking layer 127b.

According to one or more embodiments, some of the dislocations 128 that penetrate the first dislocation blocking layer 127a and propagate into the second high-resistance layer 126b may contact the bottom surface of the dislocation blocking patterns dp2 located in the second dislocation blocking layer 127b. In this case, the dislocations 128 contact the second dislocation blocking patterns dp2 may no longer propagate to other areas within the high-resistance layer 126. Accordingly, the third high-resistance layer 126c may have a lower dislocation density compared to the second high-resistance layer 126b. According to one or more embodiments, the third high-resistance layer 126c, the second high-resistance layer 126b, and the first high-resistance layer 126a may have a lower dislocation density, in that order. That is, the second high-resistance layer 126b may have a lower dislocation density than the first high-resistance layer 126a, and the third high-resistance layer 126c may have a lower dislocation density than the second high-resistance layer 126b.

As shown in FIG. 9, the dislocation density at the interface between the high-resistance layer 126 and the channel layer 132 may be further reduced compared to the semiconductor devices described above, and accordingly, the electrical characteristics of the semiconductor device may be further improved.

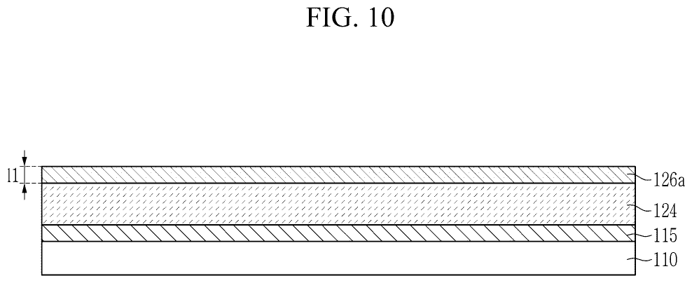

Next, with reference to FIGS. 10 to 20, a method of manufacturing a semiconductor device according to one or more embodiments will be described.

FIG. 10 to FIG. 20 are cross-sectional views illustrating a method of manufacturing a semiconductor device according to one or more embodiments.

As shown in FIGS. 10 to 14, the seed layer 115 and the buffer layer 120 may be sequentially formed on the substrate 110. The buffer layer 120 may include a superlattice layer 124 and a high-resistance layer 126.

Referring to FIG. 10, the seed layer 115 and the superlattice layer 124 may be formed on the substrate 110.

The substrate 110 may include a semiconductor material. For example, the substrate 110 may include sapphire, Si, SiC, AlN, GaN, or a combination thereof. The substrate 110 may be an SOI substrate. However, the material of the substrate 110 is not limited thereto, and any commonly used substrate may be applied.

The seed layer 115 may be formed on the substrate 110. In the final structure of the semiconductor device according to one or more embodiments, the seed layer 115 may be located between the substrate 110 and the buffer layer 120. The seed layer 115 may be a layer that serves as a seed for growing the buffer layer 120, and may be made of a crystal lattice structure that serves as a seed for the buffer layer 120.

The superlattice layer 124 may be formed. The superlattice layer 124 may be formed using an epitaxial growth method. The superlattice layer 124 may include one or more materials selected from Group III-V materials, such as nitrides containing at least one of Al, Ga, In, and B. The superlattice layer 124 may be AlₓIn_{y}Ga_{1-x-y}N (0≤x≤1, 0≤y≤1, x+y≤1). For example, the superlattice layer 124 may include at least one of AlN, GaN, InN, InGaN, AlGaN, AlInN, and AlInGaN. As an example, the substrate 110 includes Si, the seed layer 115 includes AlN, and the superlattice layer 124 has a structure in which a layer made of AlGaN and a layer made of GaN are repeatedly stacked. The superlattice layer 124 may or may not be doped with impurities.

A high-resistance layer 126 may be formed on the superlattice layer 124. Referring to FIG. 10, a first high-resistance layer 126a may be formed on the superlattice layer 124. The first high-resistance layer 126a may be grown to the first level 11 with respect to the top surface of the superlattice layer 124. In one or more embodiments, the first level 11 may be about 50 nm.

The first high-resistance layer 126a may include the same material as the superlattice layer 124 described above. That is, the first high-resistance layer 126a may include one or more materials selected from Group III-V materials, such as nitrides containing at least one of Al, Ga, In, and B. The material included in the first high-resistance layer 126a may be AlₓIn_{y}Ga_{1-x-y}N(0≤x≤1, 0≤y≤1, x+y≤1). For example, the first high-resistance layer 126a may include at least one of AlN, GaN, InN, InGaN, AlGaN, AlInN, and AlInGaN.

The first high-resistance layer 126a may be formed directly on the superlattice layer 124 using an epitaxial growth method. For example, the first high-resistance layer 126a may be formed using a method such as metal organic chemical vapor deposition (MOCVD), molecular beam epitaxy (MBE), or atomic layer deposition (ALD). However, the method in which the first high-resistance layer 126a is formed is not limited to the thin-film growth method described above, and the first high-resistance layer 126a may be formed using various thin-film growth methods. The first high-resistance layer 126a may be grown by injecting one or more source materials and one or more precursors into a chamber having predetermined temperature and pressure conditions. For example, when the material included in the first high-resistance layer 126a is GaN to form the first high-resistance layer 126a, trimethyl gallium (TMGa) and ammonia (NH3) gas may be injected into the chamber. For example, GaN may be formed by the chemical reaction (1) below.

Ga(CH₃)₃+NH₃→GaN+3CH₄ (1)

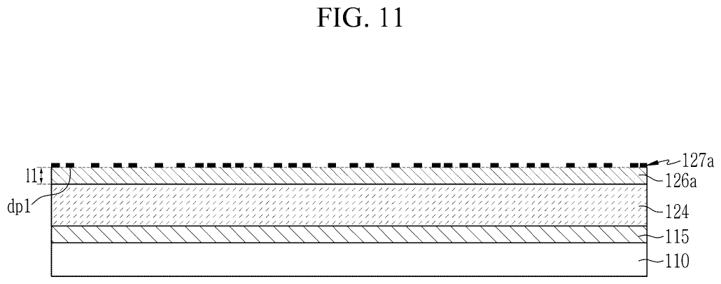

As shown in FIG. 11, a first dislocation blocking layer 127a may be formed on the first high-resistance layer 126a. The first dislocation blocking layer 127a may include a plurality of first dislocation blocking patterns dp1.

The first dislocation blocking patterns dp1 may be formed on the top surface of the first high-resistance layer 126a. The first dislocation blocking patterns dp1 may be located at the first level 11. The first dislocation blocking patterns dp1 may be arranged at irregular intervals such that the first dislocation blocking patterns dp1 are spaced apart at varied distances along the horizontal direction at a thickness of the first level 11.

In one or more embodiments, the first dislocation blocking patterns dp1 may include an insulating material. At least one element among the elements constituting the material included in the first high-resistance layer 126a may also be included as an element constituting the insulating material included in the first dislocation blocking patterns dp1. In one or more embodiments, when the first high-resistance layer 126a includes GaN, the first dislocation blocking patterns dp1 may be nitride containing a material other than gallium (Ga) as an element. For example, the first dislocation blocking patterns dp1 may include InNx. In one or more embodiments, the first dislocation blocking patterns dp1 may be formed in-situ in the same process as the process of forming the first high-resistance layer 126a. That is, the first dislocation blocking patterns dp1 may be formed continuously with the first high-resistance layer 126a within the same chamber (i.e., without moving the position of the semiconductor device being manufactured) immediately after forming the first high-resistance layer 126a, and the dislocation blocking layer 127a may be formed through a traditional process. At least one of the materials used to form the first high-resistance layer 126a may also be used in the process of forming the first dislocation blocking patterns dp1. For example, when the first high-resistance layer 126a includes GaN and the first dislocation blocking patterns dp1 includes InNx, trimethyl indium (TMIn) may be used to form the first dislocation blocking patterns dp1 gas, and ammonia (NH₃) gas may be injected. Trimethyl gallium (TMGa) used to form the first high-resistance layer 126a may not be injected into the chamber.

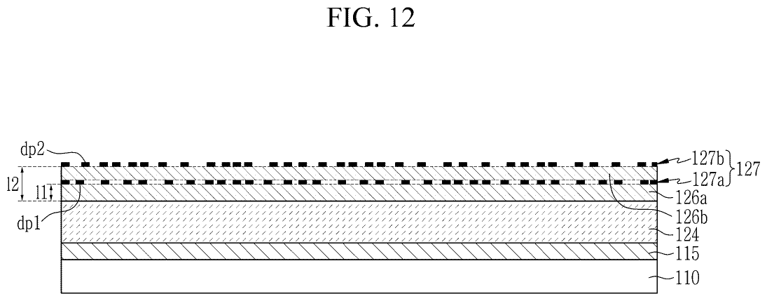

As shown in FIG. 12, the second high-resistance layer 126b and the second dislocation blocking layer 127b may be sequentially formed on the first high-resistance layer 126a and the first dislocation blocking layer 127a. The second high-resistance layer 126b may also be formed between the first dislocation blocking patterns dp1.

The second high-resistance layer 126b may be formed by the second level 12 with respect to the top surface of the superlattice layer 124. The second level 12 may be higher than the first level 11. In one or more embodiments, the second level may be about 100 nm.

The second high-resistance layer 126b may include the same material as the first high-resistance layer 126a. That is, the second high-resistance layer 126b may include one or more materials selected from Group III-V materials, such as nitrides containing at least one of Al, Ga, In, and B. The material included in the second high-resistance layer 126b may be AlₓIn_{y}Ga_{1-x-y}N (0≤x≤1, 0≤y≤1, x+y≤1). For example, the first high-resistance layer 126a may include at least one of AlN, GaN, InN, InGaN, AlGaN, AlInN, and AlInGaN.

The second high-resistance layer 126b may be formed on the first high-resistance layer 126a and the first dislocation blocking layer 127a using an epitaxial growth method. The second high-resistance layer 126b may be grown in the same manner as the first high-resistance layer 126a. In one or more embodiments, the second high-resistance layer 126b may be formed in-situ in the same process as the process for forming the first high-resistance layer 126a and the first dislocation blocking layer 127a. Among the entire upper surface area of the first high-resistance layer 126a, the portion exposed between the first dislocation blocking patterns dp1 may be used as a seed for forming the second high-resistance layer 126b. In other words, the material (e.g., GaN) included in the second high-resistance layer 126b may be grown from the top surface of the first high-resistance layer 126a. However, the material (e.g., GaN) included in the second high-resistance layer 126b may not grow in a portion blocked by the first dislocation blocking patterns dp1. Accordingly, the material included in the second high-resistance layer 126b may not grow upward but may grow in the lateral direction in the area adjacent to the first dislocation blocking patterns dp1. In this case, the direction in which the dislocations contained within the second high-resistance layer 126b propagate may also change to the lateral direction.

A second dislocation blocking layer 127b may be formed on the second high-resistance layer 126b. The second dislocation blocking layer 127b may include a plurality of second dislocation blocking patterns dp2.

The second dislocation blocking patterns dp2 may be located at the second level 12. The second dislocation blocking patterns dp2 may be arranged at irregular intervals such that the second dislocation blocking patterns dp2 are spaced apart at varied distances along the horizontal direction at a thickness of the second level 11. Since the material contained in the second dislocation blocking layer 127b and the specific method of forming the second dislocation blocking layer 127b may be the same as those of the first dislocation blocking layer 127a, repeated descriptions may be omitted.

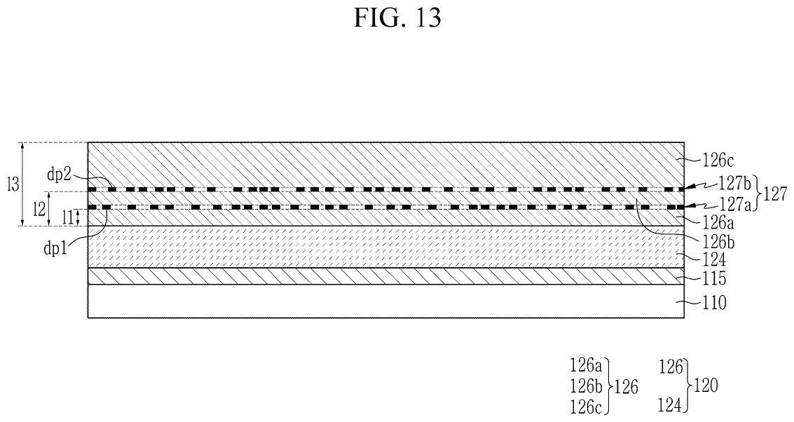

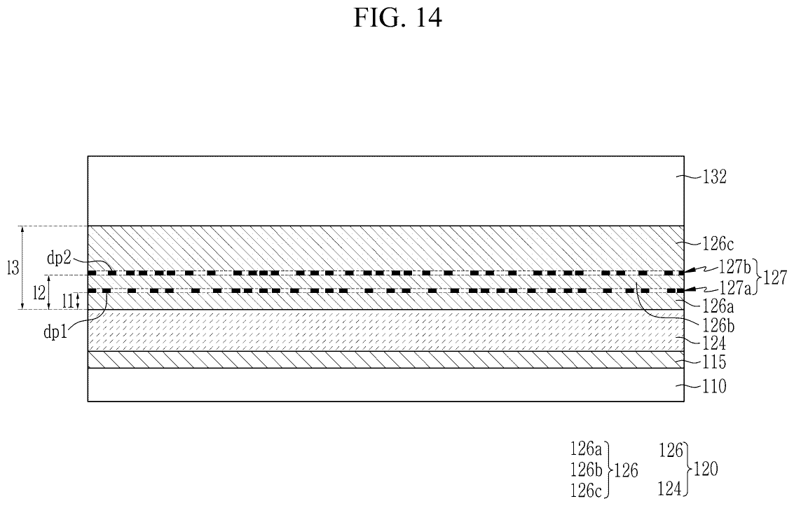

As shown in FIG. 13, a third high-resistance layer 126c may be formed on the second high-resistance layer 126b and the second dislocation blocking layer 127b. The third high-resistance layer 126c may also be formed between the second dislocation blocking patterns dp2. In one or more embodiments, the third high-resistance layer 126c may form the high-resistance layer 126 together with the first high-resistance layer 126a and the second high-resistance layer 126b. The third high-resistance layer 126c may be formed as much as the third level 13 with respect to the top surface of the superlattice layer 124. The third level 13 may be higher than the first level (11) and the second level 12. The second dislocation blocking layer 127b may be located closer to the lower surface of the high-resistance layer 126 in the vertical direction than the upper surface of the high-resistance layer 126. The difference between the third level 13 and the second level 12 may be larger than the second level 12. The third high-resistance layer 126c may include the same material as the first high-resistance layer 126a and the second high-resistance layer 126b. That is, the third high-resistance layer 126c may include one or more materials selected from Group III-V materials, such as nitrides containing at least one of Al, Ga, In, and B. The material included in the third high-resistance layer 126c may be AlₓIn_{y}Ga_{1-x-y}N (0≤x≤1, 0≤y≤1, x+y≤1). For example, the third high-resistance layer 126c may include at least one of AlN, GaN, InN, InGaN, AlGaN, AlInN, and AlInGaN.

The third high-resistance layer 126c may be formed directly on the second high-resistance layer 126b and the second dislocation blocking layer 127b using an epitaxial growth method. The third high-resistance layer 126c may be grown in the same manner as the second high-resistance layer 126b. In one or more embodiments, the third high-resistance layer 126c may be formed in-situ in the same process as the process of forming the second high-resistance layer 126b and the second dislocation blocking layer 127b. Among the entire upper surface area of the second high-resistance layer 126b, the portion exposed between the second dislocation blocking patterns dp2 may be used as a seed for forming the third high-resistance layer 126c. In other words, the material (e.g., GaN) included in the third high-resistance layer 126c may be grown from the top surface of the second high-resistance layer 126b. However, the material (e.g., GaN) included in the third high-resistance layer 126c may not grow in the portion blocked by the second dislocation blocking patterns dp2. Accordingly, the material included in the third high-resistance layer 126c may not grow upward but may grow laterally in the area adjacent to the second dislocation blocking patterns dp2. In this case, the direction in which the dislocations contained within the third high-resistance layer 126c propagate may also change to the lateral direction.

In one or more embodiments, the high-resistance layers 126a, 126b, and 126c may include GaN doped with carbon (C). Carbon (C) doped into GaN may come from trimethyl gallium (TMGa) injected into the chamber during GaN growth. The amount of carbon (C) doped into GaN may vary depending on the temperature inside the chamber where GaN is grown. For example, as the temperature inside the chamber decreases, the doping efficiency of carbon (C) doped into GaN grown inside the chamber may increase. As the amount of carbon (C) doped increases, the electrical resistance of GaN may increase. When the high-resistance layers 126a, 126b, and 126c are each grown, the temperature inside the chamber may be lower than the temperature at which the channel layer 132 (see FIG. 14) is grown. For example, the channel layer 132 may be grown at about 1000° C. or higher, while the first to third high-resistance layers 126a, 126b, and 126c may be grown at about 850° C. to about 950° C. Accordingly, the high-resistance layers 126a, 126b, and 126c may have higher electrical resistance than the channel layer 132. However, the high-resistance layers 126a, 126b, and 126c may contain a larger number of defects (for example, penetration dislocations) within them, as they are grown at a lower temperature compared to the channel layer 132. In one or more embodiments, as the dislocation blocking layer 127 is included within the high-resistance layers 126a, 126b, and 126c, even when the high-resistance layers 126a, 126b, and 126c are grown at a relatively low temperature, the density of dislocations that may exist inside may be reduced, and thus a high-quality thin film may be formed.

Referring to FIG. 14, a channel layer 132 may be formed on the high-resistance layer 126. The channel layer 132 may be formed using an epitaxial growth method. As the lattice structure of Si and the lattice structure of GaN are different, it may not be easy to grow the channel layer 132 made of GaN directly on the substrate 110 made of Si. In the semiconductor device manufacturing method according to one or more embodiments, the buffer layer 120 may be first formed on the substrate 110 and then the channel layer 132 is formed, such that the lattice structure of the channel layer 132 may be stably formed.

The channel layer 132 may be made of the same semiconductor material as the superlattice layer 124 and the high-resistance layer 126. However, considering the role of each layer and the performance required for the semiconductor device, the material composition ratio of each layer may be different. The channel layer 132 may include one or more materials selected from Group III-V materials, such as nitrides containing at least one of Al, Ga, In, and B. The channel layer 132 may be made of a single layer or multiple layers. The channel layer 132 may be AlₓIn_{y}Ga_{1-x-y}N (0≤x≤1, 0≤y≤1, x+y=1). For example, the channel layer 132 may include at least one of AlN, GaN, InN, InGaN, AlGaN, AlInN, and AlInGaN. The channel layer 132 may be a layer doped with impurities or a layer not doped with impurities. The thickness of the channel layer 132 may be several hundred nm or less.

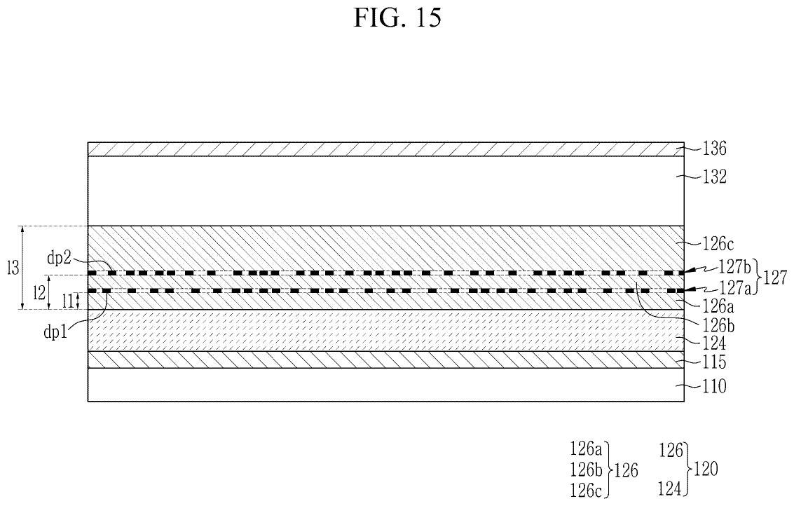

As shown in FIG. 15, a barrier layer 136 may be formed on the channel layer 132. The barrier layer 136 may be formed using an epitaxial growth method. The barrier layer 136 may be made of the same semiconductor material as the superlattice layer 124, the high-resistance layer 126, and the channel layer 132. However, considering the role of each layer and the performance required for the semiconductor device, the material composition ratio of each layer may be different. The barrier layer 136 may include one or more materials selected from Group III-V materials, such as nitrides containing at least one of Al, Ga, In, and B. The barrier layer 136 may be AlₓIn_{y}Ga_{1-x-y}N (0≤x≤1, 0≤y≤1, x+y≤1). For example, the barrier layer 136 may include at least one of AlN, GaN, InN, InGaN, AlGaN, AlInN, and AlInGaN. The barrier layer 136 may include a material having a different energy band gap than the channel layer 132. The barrier layer 136 may have a higher energy band gap than the channel layer 132.

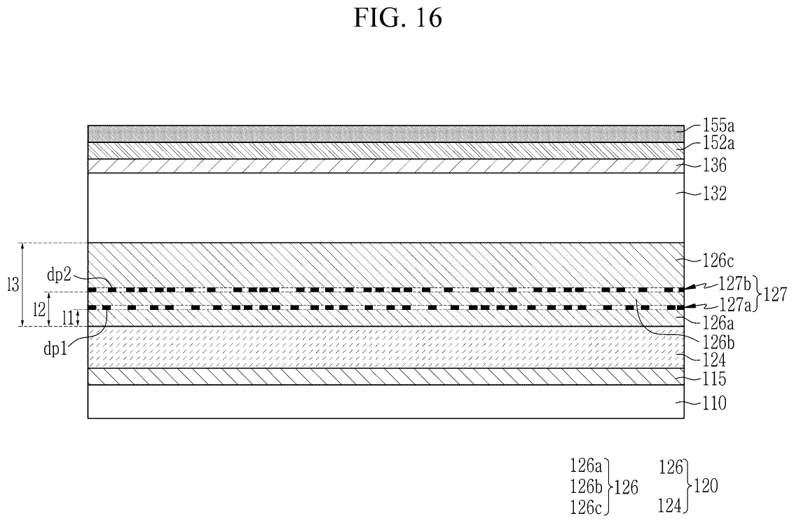

As shown in FIG. 16, a gate semiconductor material layer 152a and a gate electrode material layer 155a may be sequentially formed on the barrier layer 136.

The gate semiconductor material layer 152a may be continuously formed on the barrier layer 136 using an epitaxial growth method. The gate semiconductor material layer 152a may be made of the same semiconductor material as the buffer layer 120, the channel layer 132, and the barrier layer 136. However, considering the role of each layer and the performance required for the semiconductor device, the material composition ratio of each layer may be different. The gate semiconductor material layer 152a may include one or more materials selected from Group III-V materials, such as nitrides containing at least one of Al, Ga, In, and B. The gate semiconductor material layer may be 152a AlₓIn_{y}Ga_{1-x-y}N (0≤x≤1, 0≤y≤1, x+y≤1). For example, the gate semiconductor material layer 152a may include at least one of AlN, GaN, InN, InGaN, AlGaN, AlInN, and AlInGaN.

In one or more embodiments, the gate semiconductor material layer 152a may include GaN and may be doped with impurities. The gate semiconductor material layer 152a may be doped with a p-type impurity, such as magnesium (Mg).

A gate electrode material layer 155a may be formed on the gate semiconductor material layer 152a. The gate electrode material layer 155a may be formed using a deposition process. For example, the gate electrode material layer 155a may be formed using physical vapor deposition (PVD), thermal chemical vapor deposition (CVD), low-pressure CVD (LP-CVD), plasma enhanced CVD (PE-CVD), or it may be formed using at least one of the atomic layer deposition (ALD) technologies, but is not limited thereto.

The gate electrode material layer 155a may include a conductive material. For example, the gate electrode material layer 155a may include metal, metal alloy, conductive metal nitride, metal silicide, a doped semiconductor material, conductive metal oxide, or conductive metal nitride. For example, the gate electrode material layer 155a may be formed of titanium nitride (TIN), tantalum carbide (TaC), tantalum nitride (TaN), titanium silicon nitride (TiSiN), tantalum silicon nitride (TaSiN), or tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TiC), tantalum carbonitride (TaCN), tungsten (W), aluminum (AI), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), it may include rhodium (Rh), palladium (Pd), iridium (Ir), osmium (Os), silver (Ag), gold (Au), zinc (Zn), vanadium (V), or a combination thereof, embodiments are not limited thereto. The gate electrode material layer 155a may be made of a single layer or multiple layers.

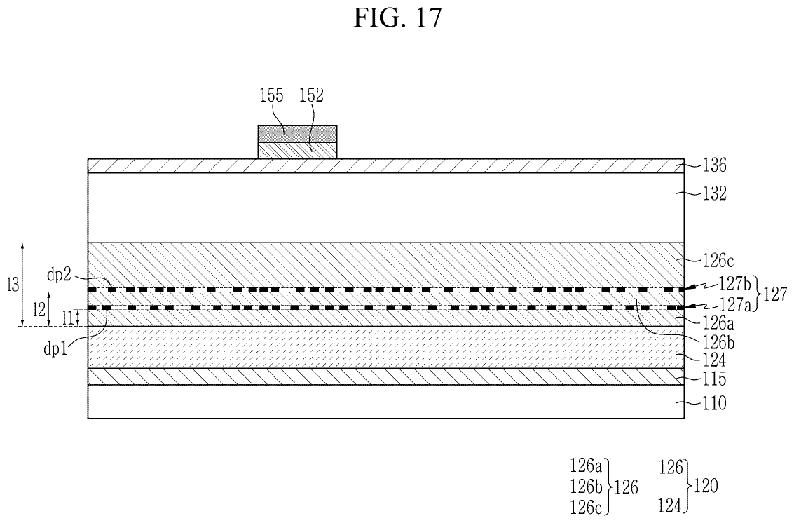

As shown in FIG. 17, the gate electrode 155 and the gate semiconductor layer 152 may be formed by patterning the gate electrode material layer 155a and the gate semiconductor material layer 152a using a photo and etching process.

For example, a hard mask layer and a photoresist layer may be sequentially formed on the gate electrode material layer 155a. A photoresist pattern may be formed by patterning the photoresist layer using a photo process. A hard mask pattern may be formed by etching the hard mask layer using a photoresist pattern as a mask. By continuously etching the gate electrode material layer 155a and the gate semiconductor material layer 152a using the hard mask pattern as a mask, at least a portion of the gate electrode material layer 155a and the gate semiconductor material layer 152a may be removed. Accordingly, the remaining portion of the gate electrode material layer 155a may become the gate electrode 155. Additionally, the portion of the gate semiconductor material layer 152a that remains may become the gate semiconductor layer 152. The gate electrode 155 may be in Schottky contact or ohmic contact with the gate semiconductor layer 152.

By patterning the gate semiconductor material layer 152a and the gate electrode material layer 155a using the same mask, the gate semiconductor layer 152 and the gate electrode 155 may have the same pattern. That is, the gate semiconductor layer 152 and the gate electrode 155 may have the same planar shape. In cross-section, the gate semiconductor layer 152 and the gate electrode 155 may have the same width. The gate semiconductor layer 152 and the gate electrode 155 may completely overlap in the vertical direction, and the upper surface of the gate semiconductor layer 152 may be entirely covered by the gate electrode 155.

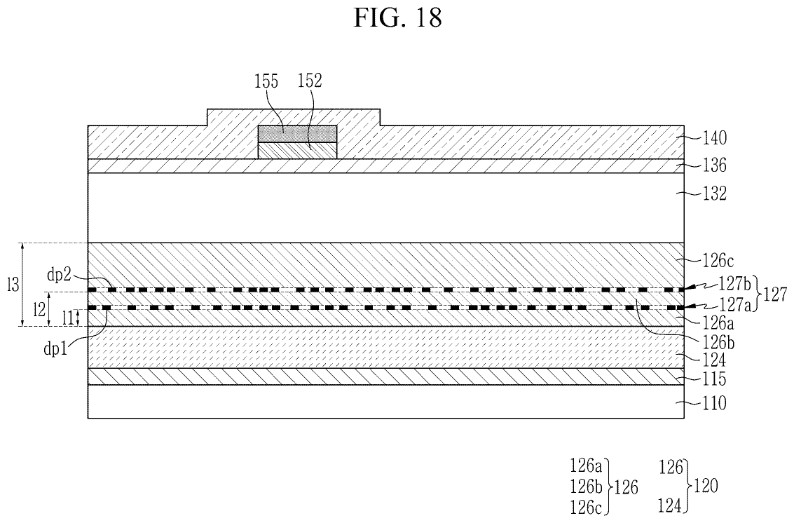

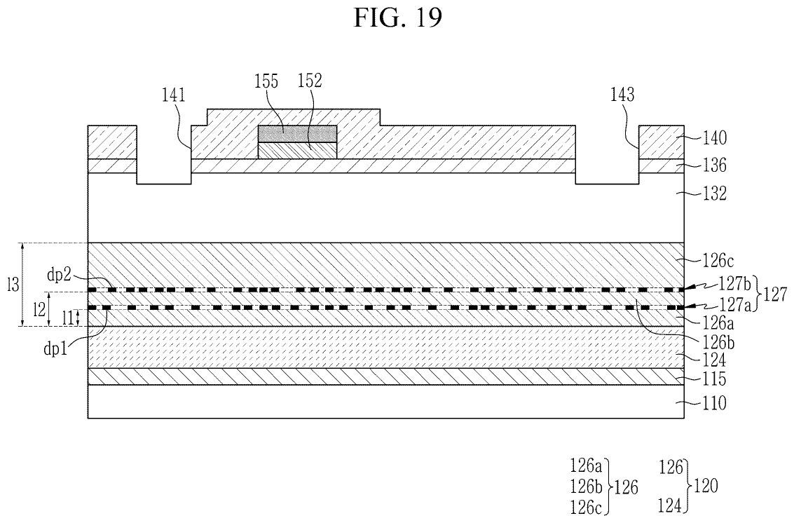

As shown in FIG. 18, the protective layer 140 may be formed to cover the gate electrode 155, a portion of the upper surface of the barrier layer 136, and the side surfaces of the gate semiconductor layer 152 and the gate electrode 155. The protective layer 140 may include an insulating material. For example, the protective layer 140 may include materials such as SiO₂, SiN, SiON, Al₂O₃, etc. The protective layer 140 is shown as a single layer, but may be composed of multiple layers in some cases. The protective layer 140 may be formed by sequentially depositing different materials. Alternatively, the protective layer 140 may be formed of several layers with different characteristics by using the same material and varying deposition conditions. In particular, the portion of the protective layer 140 adjacent to the barrier layer 136 may be made of an insulating material of much higher quality than other portions. This is to prevent electrons forming a channel from being trapped in the channel layer 132 located below the barrier layer 136. The portion of the protective layer 140 that contacts the barrier layer 136 may be made of SiO₂.

As shown in FIG. 19, a first trench 141 and a second trench 143 may be formed by patterning the protective layer 140. Some areas of the barrier layer 136 and the channel layer 132 may be patterned together.

For example, a photoresist pattern may be formed on the protective layer 140, and the protective layer 140, the barrier layer 136, and the channel layer 132 may be sequentially etched using this as a mask. The barrier layer 136 may be penetrated by the first trench 141 and the second trench 143, and the trenches 141 and 143 may extend into the channel layer 132 such that the upper surface of the channel layer 132 may be recessed. The channel layer 132 may not be fully penetrated by the first trench 141 or the second trench 143. That is, the depth at which the upper surface of the channel layer 132 is recessed may be smaller than the total thickness of the channel layer 132. The depth at which the upper surface of the channel layer 132 is recessed may be much smaller than the total thickness of the channel layer 132. For example, the depth at which the upper surface of the channel layer 132 is recessed may be up to about 30% of the total thickness of the channel layer 132. Additionally, the depth at which the upper surface of the channel layer 132 is recessed may be smaller than the thickness of the barrier layer 136. However, embodiments are not limited thereto, and the depth at which the upper surface of the channel layer 132 is recessed may vary. The side of the barrier layer 136 may be exposed to the outside by the first trench 141 and the second trench 143, and the top and side surfaces of the channel layer 132 may be exposed. The channel layer 132 may form the bottom surface and side surfaces of the first trench 141 and the second trench 143, and the barrier layer 136 may form the side surfaces of the first trench 141 and the second trench 143.

The first trench 141 and the second trench 143 may be spaced apart from each other. The first trench 141 and the second trench 143 may be located on both sides of the gate electrode 155. The first trench 141 may be positioned on one side of the gate electrode 155 to be spaced apart from the gate electrode 155. The second trench 143 may be positioned on the other side of the gate electrode 155 to be spaced apart from the gate electrode 155. The distance between the first trench 141 and the gate electrode 155 may be smaller than the distance between the second trench 143 and the gate electrode 155. Although the shapes of the first trench 141 and the second trench 143, such as width and depth, are shown to be similar, they are not limited thereto. The shapes of the first trench 141 and the second trench 143 may be changed in various ways.

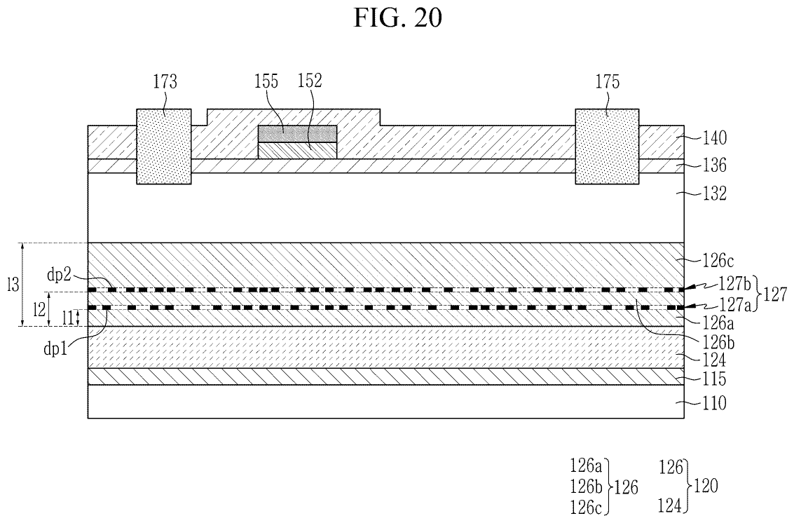

As shown in FIG. 20, a conductive material may be deposited on the protective layer 140 in which the first trench 141 and the second trench 143 are formed and may be patterned to form the source electrode 173 and the drain electrode 175.

The source electrode 173 and the drain electrode 175 may include a conductive material. For example, the source electrode 173 and the drain electrode 175 may include metal, metal alloy, conductive metal nitride, metal silicide, a doped semiconductor material, conductive metal oxide, or conductive metal nitride. The source electrode 173 and the drain electrode 175 may be made of a single layer or multiple layers. For example, the source electrode 173 and the drain electrode 175 may be formed by stacking a plurality of conductive layers containing different materials and then patterning them. The plurality of conductive layers may be etched simultaneously or sequentially using one mask pattern. For example, Ti, Al, Ti, and TiN may be sequentially stacked and then patterned to form the source electrode 173 and the drain electrode 175. The thickness of the four conductive layers constituting the source electrode 173 and the drain electrode 175 may be similar or different. For example, a layer made of Al may be relatively thick compared to other layers.

The source electrode 173 may be formed to fill the interior of the first trench 141. Within the first trench 141, the source electrode 173 may contact the channel layer 132 and the barrier layer 136. The source electrode 173 may contact the side surfaces of the channel layer 132 and the barrier layer 136. The source electrode 173 may cover the side surfaces of the channel layer 132 and the barrier layer 136. The source electrode 173 may be electrically connected to the channel layer 132 through the first trench 141.

The drain electrode 175 may be formed to fill the interior of the second trench 143. Within the second trench 143, the drain electrode 175 may contact the channel layer 132 and the barrier layer 136. The drain electrode 175 may contact the side surfaces of the channel layer 132 and the barrier layer 136. The drain electrode 175 may cover the side surfaces of the channel layer 132 and the barrier layer 136. The drain electrode 175 may be electrically connected to the channel layer 132 through the second trench 143.

The source electrode 173 and the drain electrode 175 may be in ohmic contact with the channel layer 132. The region contacting the source electrode 173 and the drain electrode 175 within the channel layer 132 may be doped at a relatively high concentration compared to other regions. For example, the channel layer 132 may be doped by an ion implant process, an annealing process, etc. However, embodiments are not limited thereto, and the doping process of the channel layer 132 may be performed through various other processes. The doping process of the channel layer 132 may be performed before forming the source electrode 173 and the drain electrode 175. In some cases, the channel layer 132 may not be doped.

Inside the channel layer 132, a 2DEG 134 may be formed in a portion adjacent to the barrier layer 136. The 2DEG 134 may be located at the interface between the channel layer 132 and the barrier layer 136. The 2DEG 134 may be located in the drift region DTR between the source electrode 173 and the drain electrode 175. A depletion region DPR may be formed in the channel layer 132 by the gate semiconductor layer 152 having a different energy band gap than the barrier layer 136. Accordingly, a semiconductor device according to one or more embodiments may have normally off characteristics. That is, the semiconductor device according to one or more embodiments may be a normally off HEMT. In the gate-off state, the 2DEG 134 may be located in the drift region DTR excluding the depletion region DPR of the channel layer 132. In the gate-on state, the flow of the 2DEG 134 continues within the depletion region DPR, and the 2DEG 134 may be located entirely within the drift region DTR. However, embodiments are not limited thereto, and the semiconductor device according to one or more embodiments may have normally on characteristics.

Power semiconductor devices may be classified according to materials, and examples include SiC power semiconductor devices and GaN power semiconductor devices. By manufacturing power semiconductor devices using SiC or GaN instead of silicon wafers, the disadvantage of silicon, which has unstable characteristics at high temperatures, may be compensated. SiC power semiconductor devices are resistant to high temperatures and have low power loss, and may be suitable for electric vehicles, renewable energy systems, etc. GaN power semiconductor devices require high costs, but are efficient in terms of speed and may be suitable for high-speed charging of mobile devices.

Semiconductor devices according to one or more embodiments may include dislocation blocking patterns arranged at irregular intervals within the high-resistance layer, and accordingly, the defect density inside the high-resistance layer may be reduced, thereby improving the electrical characteristics and reliability of the semiconductor device.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor device, comprising:
a substrate;
a buffer layer on the substrate, the buffer layer comprising a first high-resistance layer and a second high-resistance layer;
a first dislocation blocking layer between the first high-resistance layer and the second high-resistance layer;
a channel layer on the buffer layer, the channel layer comprising a material having a first energy band gap;
a barrier layer on the channel layer, the barrier layer comprising a material having a second energy band gap that is different from the first energy band gap;
a gate electrode on the barrier layer; and
a gate semiconductor layer between the barrier layer and the gate electrode,
wherein the first dislocation blocking layer comprises a plurality of first dislocation blocking patterns arranged at irregular intervals.

2. The semiconductor device of claim 1, wherein each of the plurality of first dislocation blocking patterns is greater than or equal to 100 nm and less than or equal to 200 nm.

3. The semiconductor device of claim 1, wherein a thickness of each of the plurality of first dislocation blocking patterns is less than or equal to 20 nm.

4. The semiconductor device of claim 1, wherein at least one of the plurality of first dislocation blocking patterns comprises InNx.

5. The semiconductor device of claim 1, wherein the plurality of first dislocation blocking patterns are configured to block dislocations from extending to an upper surface of the second high-resistance layer such that at least one dislocation blocking pattern of the plurality of first dislocation blocking patterns has a bottom surface contacting one end of a dislocation extending from a lower surface of the first high-resistance layer.

6. The semiconductor device of claim 1, wherein the buffer layer further comprises a third high-resistance layer on the second high-resistance layer,
wherein the semiconductor device further comprises a second dislocation blocking layer between the second high-resistance layer and the third high-resistance layer, and
wherein the second dislocation blocking layer comprises a plurality of second dislocation blocking patterns arranged at irregular intervals.

7. The semiconductor device of claim 1, wherein, in a vertical direction, the first dislocation blocking layer is closer to a lower surface of the second high-resistance layer than an upper surface of the first high-resistance layer.

8. The semiconductor device of claim 1, wherein each of the plurality of first dislocation blocking patterns has a curved upper surface.

9. A method of manufacturing a semiconductor device, comprising:
forming a buffer layer on a substrate, the buffer layer comprising a high-resistance layer;
forming a channel layer on the buffer layer, the channel layer comprising a material having a first energy band gap;
forming a barrier layer on the channel layer, the barrier layer comprising a material having a second energy band gap that is different from the first energy band gap;
forming a gate semiconductor layer on the barrier layer; and
forming a gate electrode on the gate semiconductor layer;
wherein the forming of the buffer layer comprises:
forming a first high-resistance layer;
forming a first dislocation blocking layer on the first high-resistance layer, the first dislocation blocking layer comprising a plurality of first dislocation blocking patterns arranged at irregular intervals; and
forming a second high-resistance layer on the first dislocation blocking layer.

10. The method of manufacturing a semiconductor device of claim 9, wherein the first dislocation blocking layer is formed in-situ within the high-resistance layer during the forming of the buffer layer.

11. The method of manufacturing a semiconductor device of claim 9, wherein the forming of the buffer layer further comprises:
forming a second dislocation blocking layer on the second high-resistance layer, the second dislocation blocking layer comprising a plurality of second dislocation blocking patterns arranged at irregular intervals, and
forming a third high-resistance layer on the second dislocation blocking layer.

12. The method of manufacturing a semiconductor device of claim 9, wherein each of the plurality of first dislocation blocking patterns is greater than or equal to 100 nm and less than or equal to 200 nm.

13. The method of manufacturing a semiconductor device of claim 9, wherein a thickness of each of the plurality of first dislocation blocking patterns is less than or equal to 20 nm.

14. The method of manufacturing a semiconductor device of claim 9, wherein at least one of the plurality of first dislocation blocking patterns comprises InNx.

15. The method of manufacturing a semiconductor device of claim 9, wherein the plurality of first dislocation blocking patterns are configured to block dislocations from extending to an upper surface of the second high-resistance layer such that at least one dislocation blocking pattern of the plurality of first dislocation blocking patterns has a bottom surface contacting one end of a dislocation extending from a lower surface of the first high-resistance layer.

16. The method of manufacturing a semiconductor device of claim 9, wherein, in a vertical direction, the first dislocation blocking layer is closer to a lower surface of the second high-resistance layer than an upper surface of the first high-resistance layer.

17. The method of manufacturing a semiconductor device of claim 9, wherein each of the plurality of first dislocation blocking patterns has a curved upper surface.

18. A semiconductor device, comprising:
a substrate;
a buffer layer on the substrate, the buffer layer comprising a first high-resistance layer and a second high-resistance layer, the first high-resistance layer and the second high-resistance layer comprising carbon-doped GaN;
a first dislocation blocking layer between the first high-resistance layer and the second high-resistance layer;
a channel layer on the buffer layer and comprising GaN, the channel layer having a first energy band gap;
a barrier layer on the channel layer and comprising AlGaN, the barrier layer having a second energy band gap that is different from the first energy band gap;
a gate electrode on the barrier layer; and
a gate semiconductor layer between the barrier layer and the gate electrode,
wherein the first dislocation blocking layer comprises a plurality of first dislocation blocking patterns arranged at irregular intervals, and
wherein a width of each of the plurality of first dislocation blocking patterns is greater than or equal to 100 nm and less than or equal to 200 nm.

19. The semiconductor device of claim 18, wherein the barrier layer further comprises a third high-resistance layer on the second high-resistance layer,
wherein the semiconductor device further comprises a second dislocation blocking layer between the second high-resistance layer and the third high-resistance layer, and
wherein the second dislocation blocking layer comprises a plurality of second dislocation blocking patterns arranged at irregular intervals.

20. The semiconductor device of claim 18, wherein each of the plurality of first dislocation blocking patterns has a curved upper surface.
